(19) United States
(12) Patent Application Publication
(10) Pub. No.: US 2013/0313653 A1
(43) Pub. Date: Nov. 28, 2013

(54) MOS Transistor with Multi-finger Gate Electrode

(71) Applicant: Helmut Brech, Lappersdorf (DE)

(72) Inventor: Helmut Brech, Lappersdorf (DE)

(73) Assignee: INFINEON TECHNOLOGIES AUSTRIA AG, Villach (AT)

(21) Appl. No.: 13/481,606

(22) Filed: May 25, 2012

(51) Int. Cl. H01L 27/105

(52) U.S. Cl. 257/379; 257/390; 257/E27.081

(57) ABSTRACT

A field effect transistor is described. In accordance with the one example, the transistor includes a semiconductor substrate, a gate pad for receiving a gate signal, a number of transistor cells integrated in the substrate, wherein each transistor cell has at least one gate electrode. The transistor further includes a number of gate runners for distributing the gate signal to the gate electrodes of the transistor cells. Each individual gate runner is electrically coupled to the gate pad via a respective gate resistor having a defined resistance.

### TECHNICAL FIELD

The present invention generally relates to the field MOS transistors, particularly power MOSFETs having a multi-finger gate electrode structure.

### BACKGROUND

Not infrequently, power MOSFETs used in switching applications may be observed to have a high-frequency oscillation (i.e., a ringing) on their gate-to-source voltage. Sometimes this ringing will be harmless. For example, it may occur after the gate voltage has reached its steady-state voltage for the period so that it has little impact on performance. However, it may be a very significant source of dissipation in the MOSFET, to the point where the MOSFET might fail because of it, especially if the ringing occurs after the MOSFET is turned off and the ringing amplitude is large enough to periodically turn on the MOSFET during this off-state.

For further discussion a single power MOSFET being driven by a low impedance driver is considered. The parasitic oscillations are a result of the parasitic inductances and capacitances that are intrinsically present in every real-world transistor and consequently each transistor may form a resonant tank circuit which, under certain conditions, can be excited into oscillation. Although the MOSFET has parasitic inductance, it should also be realized that in many cases the dominant inductance is caused by long (strip) lines. The parasitic inductance and the line inductance are in series, and both contribute to the tank circuit.

When two or more MOSFETs are connected in parallel, each transistor individually forms a resonant tank circuit, and in addition, there are other resonant tanks formed by the parallel and series combinations of the inductances and capacitances of the individual transistors and the lines connecting them. The result is that two or more MOSFETs in parallel may well oscillate even when a single one would not. In addition, the system of multiple MOSFETs is capable of oscillation at a number of different frequencies, corresponding to the various tank circuits' natural frequencies.

Not only in radio frequency (RF) power transistors, gate resistors are used to reduce the gain or increase stability. However, simply adding a gate resistor does not lead to a satisfactory performance of the transistor. Dependent on the application the gain provided by a transistor has to be chosen low by circuit design in order to ensure stability. Generally, remaining oscillations may have a negative impact on linearity and/or linearization by external circuitry may be adversely affected.

Although the parasitic oscillations have been investigated for quite a time a need remains for power transistors, which at least partially alleviate the drawbacks described above.

### SUMMARY OF THE INVENTION

A field effect transistor is described. In accordance with the one example of the invention the transistor includes a semiconductor substrate, a gate pad for receiving a gate signal, a plurality of transistor cells integrated in the substrate. Each transistor cell has at least one gate electrode. The transistor further includes a plurality of gate runners for distributing the gate signal to the gate electrodes of the transistor cells. Each individual gate runner is electrically coupled to the gate pad via a respective gate resistor having a defined resistance.

### BRIEF DESCRIPTION OF THE DRAWINGS

For invention can be better understood with reference to the following drawings and description. The components in the figures are not necessarily to scale, instead emphasis being placed upon illustrating the principles of the invention. Moreover, in the figures, like reference numerals designate corresponding parts. In the drawings:

FIG. 1 illustrates the equivalent circuit of a real-world power MOS transistor including parasitic inductances and capacitances and includes FIG. 1a, which provides an equivalent circuit of the MOSFET and FIG. 1b, which illustrates a gate driver;

FIG. 2 illustrates a commonly used circuit for driving a power MOSFET and includes FIG. 2a, which shows a cross-sectional view and FIG. 2b, which shows a top view;

FIG. 3 illustrates a common way of coupling a gate resistor to a power MOS transistor with a multi-finger gate structure; and

FIG. 4 illustrates multi-finger power MOS transistor including a gate resistor in the current path to every single gate runner (gate finger).

### DETAILED DESCRIPTION OF ILLUSTRATIVE EMBODIMENTS

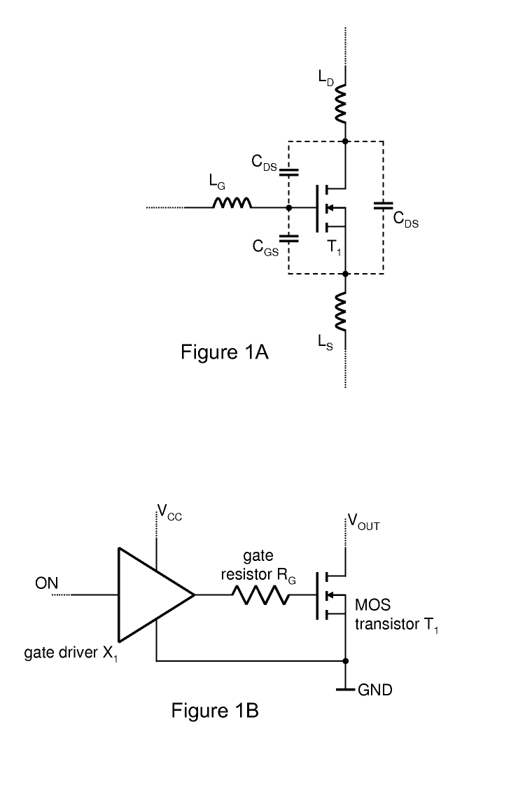

As mentioned above, the parasitic oscillations occurring in MOS transistors are a result of the parasitic inductances and capacitances which are intrinsically present in every real-world transistor. Particularly in RF applications these parasitic components usually are not negligible and have to be considered in the circuit design. FIG. 1a illustrates an equivalent circuit of a real-world transistor T₁. The parasitic capacitances effectively coupled between gate and source, gate and drain, and drain and source are denoted as C_{GS}, C_{GD}, and C_{DS}, respectively. The parasitic inductances effectively coupled to the gate, drain, and source of the transistor are denoted as L_{G}, L_{D}, and L_{S}, respectively. Consequently, each transistor may form a resonant tank circuit (i.e., an LC-resonator) which, under certain conditions, can be excited into oscillation. Connecting two or more MOSFETs in parallel may make the problem of parasitic oscillations even worse. Each transistor individually forms a resonant tank circuit and, in addition, there are further resonant tank circuits formed by the parallel and series combinations of the inductances and capacitances of the individual transistors and the lines connecting them. The result is that two or more MOSFETs coupled in parallel may well oscillate even when a single one would not.

Power MOS transistors are usually composed of a plurality of individual transistor cells that are coupled in parallel to each other so as to form one power transistor. Consequently, undesired parasitic oscillations are very likely to occur during normal operation. One measure to reduce oscillations is to reduce the parasitic inductance. Another measure is to damp the tank circuit by adding a gate resistor. A gate resistor R_{G}, as already mentioned above, is usually included between a gate pad of the (macroscopic) power MOS transistor T₁ and a respective gate driver circuit X₁ (see FIG. 1b) so as to limit the gate current thereby limiting the load current (i.e., drain current) gradient during the switching operation. Thus, a gate resistance may help to reduce parasitic oscillations.

However, one lumped gate resistor R_{G} coupled to the (external) gate electrode (i.e., the gate pad) of the power transistor does not fully solve the problem of parasitic oscillations. Oscillations may still occur due to the undamped tank circuits formed by the transistor cells connected in parallel which—dependent on the internal structure of the power transistor—may not directly be coupled via the gate resistor. Although the circuit illustrated in FIG. 1b is usually employed to drive power transistors in low frequency switching applications, similar problems as the above-mentioned oscillations and instabilities may arise in RF applications including RF power transistors.

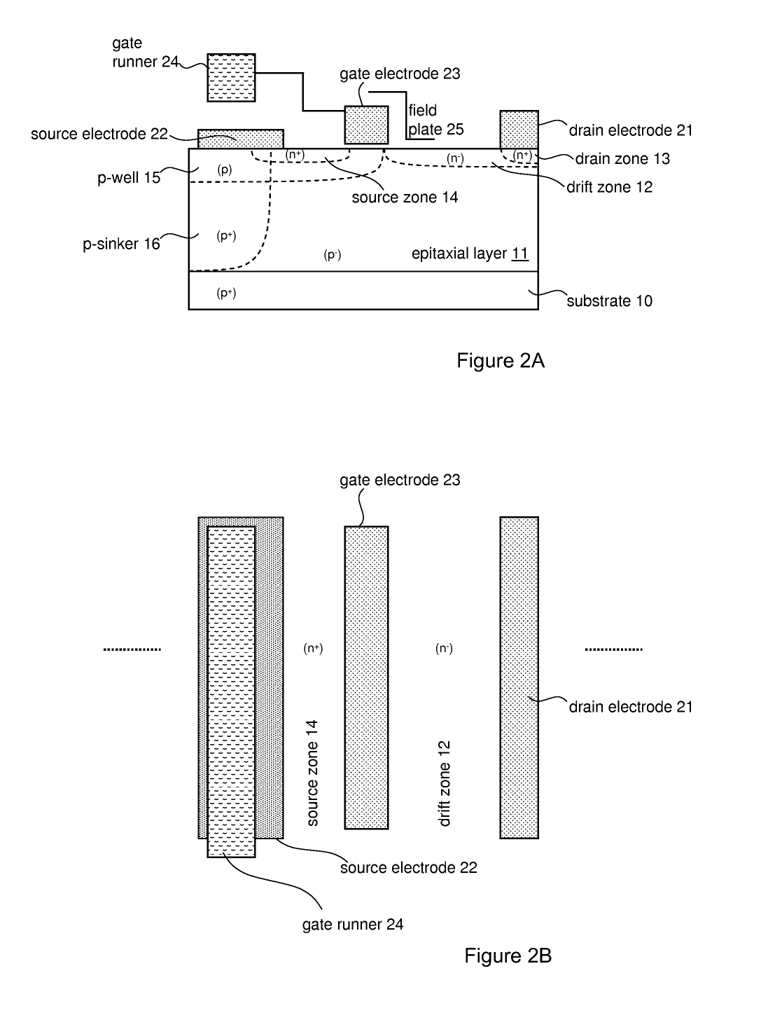

FIG. 2 illustrates one transistor cell of a lateral power MOS transistor T₁ which has a multi-finger gate structure. FIG. 2a illustrates a cross-sectional view whereas FIG. 2b illustrates the corresponding top view. It should be noted that the illustrations of FIG. 2 are not complete and details that are not required for the further discussion (e.g., oxide layers, metal layers, etc.) have been omitted so as to simplify the illustration. Further the proportions of the depicted components are not necessarily the same as in a real transistor.

The transistor cell of FIG. 2 is integrated in a semiconductor body which comprises a substrate 10 and an epitaxial layer 11. In the present example the substrate 10 and the epitaxial layer are p-doped. However, dependent on the manufacturing process an n-type semiconductor material could also be used. The epitaxial layer 11 includes a drain zone 13, a drift zone 12, a p-well 15 and a source zone 14 which is formed in the p-well 15. The p-well 15 extends to the upper surface of the semiconductor body such that the part of the p-well 15, which forms the channel region, is located between the source zone 14 and the drift zone 12. Consequently the load current can flow from the drain zone 13 through the channel region of the p-well 15 to the source zone 14 when the channel is active (i.e., conductive).

The transistor cell of FIG. 2 is an n-channel MOS transistor cell and thus the p-well is a p-doped semiconductor, whereas the source and drain zones 13, 14 are formed by doping (e.g., by implantation, diffusion) the semiconductor with n-type material. The p-sinker 16 is a heavily p-doped region which extends vertically through the epitaxial layer 11 thereby electrically connecting (short-circuiting) the substrate 10 with the source electrode 22 which is disposed on the top surface of the semiconductor body to electrically connect the source zone 14, p-well 15 and p-sinker 16.

A drain electrode 21 is disposed on the top surface of the semiconductor body to electrically connect the drain zone 13, whereas the gate electrode 23 is disposed on the top surface of the semiconductor body over the channel region of the p-well 15, but electrically isolated therefrom (e.g., by an oxide layer, not explicitly shown). The gate electrode 23 is connected with a gate runner 24 which is, e.g., arranged over the source electrode 22 but also electrically isolated therefrom (e.g., by an oxide layer, not shown). The gate runner is a metal line that distributes the gate signal across the semiconductor chip. However, materials other than metal may be used (e.g., poly-silicon).

The gate electrodes (e.g., gate electrode 23) of the individual transistor cells are electrically connected to the gate runner to receive the gate signal. The gate runner may extend in one direction from well below 100 μm to well over 1000 μm. Typically high power transistors have about 100 or more of such gate runners (gate fingers). Usually the gate runners are designed to have a minimum resistance (close to zero, e.g., less than 100 ohms or less than 10 ohms or less than 1 ohm) in order to achieve a better performance due to lower phase differences of the gate signal at different ends of the gate runners (or gate fingers).

Alternatively to the example of FIG. 2, the gate electrode 23 may be arranged in a trench which is formed in the substrate 10 thus forming a so-called trench gate transistor. Field plates 25 are known and commonly used in transistors and thus not further discussed here.

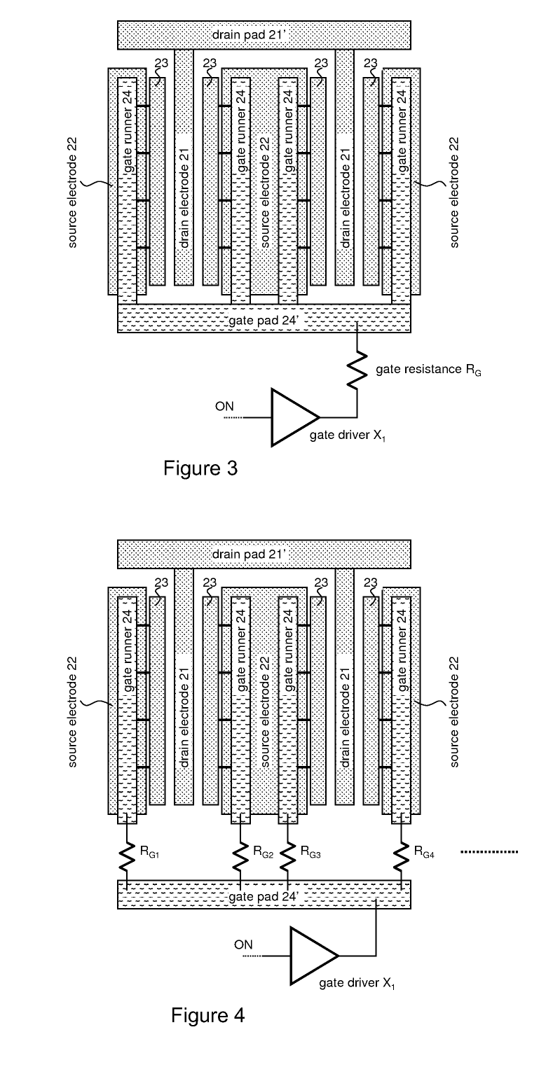

FIG. 3 illustrates a top view of four transistor cells that are formed in accordance with the example of FIG. 2. The four gate runners 24 are electrically connected to a common gate pad 24′. Similarly the four drain electrodes 21 are electrically connected to a common drain pad 21′. The common source pad (not visible in FIG. 3) is located on the back side of the substrate and connected via p-sinkers 16 (see FIG. 2a). It should be noted that an actual implementation of a power MOS transistor includes not only four cells, but hundreds or thousands of individual transistor cells coupled in parallel. However, the present example of four cells is sufficient to illustrate the concept described herein. The (lumped) gate resistor R_{G} (see also FIG. 1b) is usually connected between an external gate driver X₁ and the (macroscopic) transistor device, i.e., between the external gate driver X₁ and the gate pad 24′ that connects the plurality of gate runners 24 (gate fingers). This configuration illustrated in FIG. 3 may, however, still give rise to oscillations as already discussed above.

The power MOS transistor illustrated in FIG. 4 is, in essence, identically configured as the example of FIG. 3. One difference, however, is that the gate pad 24′ does not simply short-circuit the gate runners 24 (as it is the case in the example of FIG. 3). The gate individual runners 24 are instead coupled to the gate pad 24′ via separate gate resistors R_{G1}, R_{G2}, R_{G3}, etc., each having a well-defined (and pre-defined) resistance. To obtain the same “effective” gate resistance as in the example of FIG. 3, the resistance of the individual gate resistors R_{Gi} (i=1,2, 3, . . . , n, wherein n is the number of the gate runners 24 coupled to the gate pad) is chosen n times higher than the resistance of the “macroscopic” gate resistor R_{G} of FIG. 3. Alternatively, the “macroscopic” gate resistor R_{G} can be included but with a smaller value R_{G}′ so that the sum of the smaller resistance R_{G}′ and each individual resistor R_{G} is the same as the “macroscopic” gate resistance R_{G}. The resistance of the gate resistors is significantly higher than the resistance of the gate runners, e.g., at least 100 times or 1000 times higher.

Although various exemplary embodiments of the invention have been disclosed, it will be apparent to those skilled in the art that various changes and modifications can be made which will achieve some of the advantages of the invention without departing from the spirit and scope of the invention. Particularly the inventive concepts described herein may be applied to various types of MOS transistors such as lateral MOSFETs or IGBTs, vertical (i.e., trench gate) MOSFETs or IGBTs, and any other semiconductor devices using isolated gates to control current conduction in a channel. Such modifications to the inventive concept are intended to be covered by the appended claims. It will be obvious to those reasonably skilled in the art that other components performing the same functions may be suitably substituted. It should be mentioned that features explained with reference to a specific figure may be combined with features of other figures, even in those where not explicitly been mentioned.

What is claimed is:

1. A field effect transistor comprising:
a semiconductor substrate;
a gate pad;
a plurality of transistor cells integrated in the substrate, each transistor cell having a gate electrode;
a plurality of gate runners coupled between the gate pad and the gate electrodes of the transistor cells; and
a plurality of gate resistors, wherein each gate runner is electrically coupled to the gate pad via a respective one of the gate resistors.

2. The field effect transistor of claim 1, wherein the resistance of the gate resistors is significantly higher than the resistance of the gate runners.

3. The field effect transistor of claim 1, wherein the resistance of the gate resistors is at least 100 times higher than the resistance of the gate runners.

4. The field effect transistor of claim 3, wherein the resistance of the gate resistors is at least 1000 times higher than the resistance of the gate runners.

5. The field effect transistor of claim 1, wherein the gate electrodes and the gate runners each an elongated shape and extend parallel to each other.

6. The field effect transistor of claim 5, wherein the gate runners have the shape of a strip line extending about 100 to about 1000 microns in a straight direction.

7. The field effect transistor of claim 1, wherein the gate runners comprise poly-silicon.

8. The field effect transistor of claim 1, wherein the gate runners comprise a metal material.

9. The field effect transistor of claim 8, wherein the gate runners comprise tungsten.

10. The field effect transistor of claim 1, wherein the gate pad is configured to receive a gate signal and the gate runners are configured to distribute the gate signal to the gate electrodes.

11. The field effect transistor of claim 1, wherein each gate electrode is arranged on a top surface of the semiconductor substrate and isolated therefrom.

12. The field effect transistor of claim 1, wherein each gate electrode is arranged in a trench formed in the semiconductor substrate and is isolated from surrounding substrate.

13. The field effect transistor of claim 1, further comprising a gate driver with an output coupled to the gate pad.

14. The field effect transistor of claim 13, wherein the total resistance between the output of the gate driver and the gate pad is less than 10 ohms.

15. The field effect transistor of claim 13, further comprising a further gate resistor coupled between the output of the gate driver and the gate pad.

16. The field effect transistor of claim 1, further comprising a source pad disposed at a first surface of the substrate and a drain pad disposed at a second surface of the substrate, the first surface opposite the second surface.

17. The field effect transistor of claim 1, wherein the plurality of gate runners comprises more than 1000 gate runners.

18. A field effect transistor comprising:
a semiconductor substrate;
a gate pad configured to receive a gate signal;
a plurality of transistor cells integrated in the substrate, each transistor cell having a gate electrode;
a plurality of gate runners coupled to distribute the gate signal to the gate electrodes of the transistor cells; and
means for suppressing ringing coupled between the gate pad and each of gate runners.
